(19) United States
(12) Patent Application Publication
(10) Pub. No.: US 2019/0310330 A1
(43) Pub. Date: Oct. 10, 2019

(54) MULTI-TURN MAGNETIC RESONANCE IMAGING (MRI) ARRAY COIL OPERABLE AT LOW MAGNETIC FIELD STRENGTH

(71) Applicant: Quality Electrodynamics, LLC, Mayfield Village, OH (US)

(72) Inventors: Xiaoyu Yang, Indiana, PA (US); Haoqin Zhu, Mayfield Village, OH (US); Yong Wu, Shaker Heights, OH (US); Tsinghua Zheng, Chesterland, OH (US)

(21) Appl. No.: 16/377,502

(22) Filed: Apr. 8, 2019

Related U.S. Application Data
(60) Provisional application No. 62/655,323, filed on Apr. 10, 2018.

(51) Int. Cl. G01R 33/34; G01R 33/3415; G01R 33/36

(52) U.S. Cl. CPC G01R 33/34084; G01R 33/36; G01R 33/34007; G01R 33/3415

(57) ABSTRACT

Embodiments relate to multi-turn coil elements and arrays of multi-turn coil elements that can be employed at low B₀ field strength (e.g., 1.5 T or less). One example embodiment comprises a coil array configured to operate in at least one of a transmit (Tx) mode or a receive (Rx) mode, the coil array comprising: a plurality of multi-turn coil elements, each multi-turn coil element of the plurality of multi-turn coil elements comprising: an associated LC coil of that multi-turn coil element, comprising at least one associated coil inductor, at least one associated coil capacitor, and an associated loop comprising at least two turns; wherein the plurality of multi-turn coil elements are arranged into one or more rows, wherein the plurality of multi-turn coil elements are arranged into one or more columns, and wherein the MRI RF coil array is configured to operate at a B₀ field of 1.5 T or less.

### REFERENCE TO RELATED APPLICATIONS

This application claims the benefit of U.S. Provisional Patent Applications No. 62/655,323 filed Apr. 10, 2018, entitled “MULTI-TURN MAGNETIC RESONANCE IMAGING (MRI) ARRAY COIL OPERABLE AT LOW MAGNETIC FIELD STRENGTH”, the contents of which are herein incorporated by reference in their entirety.

### BACKGROUND

Magnetic resonance imaging (MRI) involves the transmission and receipt of radio frequency (RF) energy. RF energy may be transmitted by a coil. Resulting magnetic resonance (MR) signals may also be received by a coil. In early MRI, RF energy may have been transmitted from a single coil and resulting MR signals received by a single coil. Later, multiple receivers may have been used in parallel acquisition techniques. Similarly, multiple transmitters may have been used in parallel transmission (pTx) techniques.

RF coils create the B₁ field that rotates the net magnetization in a pulse sequence. RF coils may also detect precessing transverse magnetization. Thus, RF coils may be transmit (Tx) coils, receive (Rx) coils, or transmit and receive (Tx/Rx) coils. An imaging coil should be able to resonate at a selected Larmor frequency. Imaging coils include inductive elements and capacitive elements. The inductive elements and capacitive elements have been implemented according to existing approaches using two terminal passive components (e.g., capacitors). The resonant frequency, f, of an RF coil is determined by the inductance (L) and capacitance (C) of the inductor capacitor circuit according to equation (1):

$$f = \frac{1}{2 π \sqrt{LC}} \qquad ( 1 )$$

Imaging coils may need to be tuned. Tuning an imaging coil may include varying the value of a capacitor. Recall that frequency: f=ω/(2π), wavelength in vacuum: λ=c/f, and λ=4.7 m at 1.5 T. Recall also that the Larmor frequency: f₀=γ B₀/(2π), where (for ¹H nuclei) γ/(2π)=42.58 MHz/T; at 1.5 T, f₀=63.87 MHz; at 3 T, f₀=127.73 MHz; at 7 T, f₀=298.06 MHz. Basic circuit design principles include the fact that capacitors add in parallel (impedance 1/(jCω)) and inductors add in series (impedance jLω).

### BRIEF DESCRIPTION OF THE DRAWINGS

FIG. 1 is a block diagram illustrating an example MRI (Magnetic Resonance Imaging) apparatus that can be configured with example MRI RF (Radio Frequency) coils, coil elements, coil arrays, or circuitry according to one or more embodiments described herein.

FIG. 2 is a diagram illustrating an example one-turn coil element, as discussed in connection with various aspects disclosed herein.

FIG. 3 is a diagram illustrating an example two-turn coil element that can be employed in or as a RF antenna in a MRI apparatus, according to various aspects discussed herein.

FIG. 4 is a diagram illustrating an example coil array that can be employed as a RF antenna in a MRI apparatus, according to various aspects discussed herein.

FIG. 5 is a diagram illustrating an example apparatus comprising an array of multi-turn coil elements that can be employed as a RF antenna in a MRI apparatus, according to various aspects discussed herein.

### DETAILED DESCRIPTION

The present disclosure will now be described with reference to the attached drawing figures, wherein like reference numerals are used to refer to like elements throughout, and wherein the illustrated structures and devices are not necessarily drawn to scale.

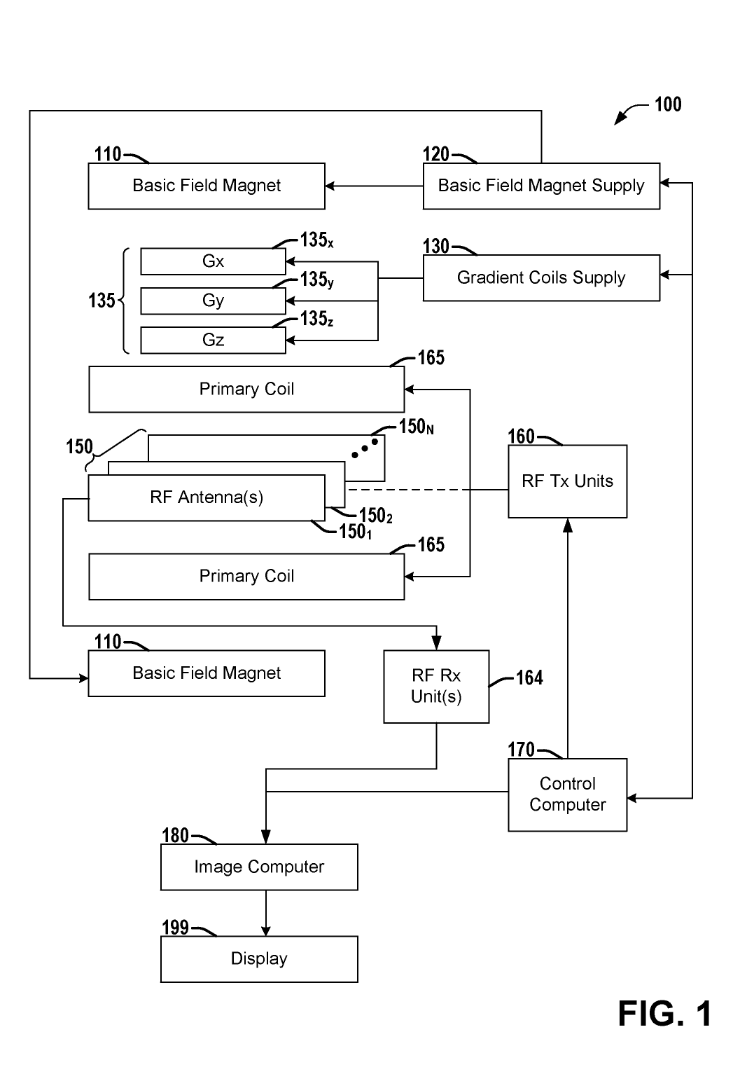

Embodiments described herein can be implemented in a MRI (Magnetic Resonance Imaging) system using any suitably configured hardware and/or software. Referring to FIG. 1, illustrated is an example MRI apparatus 100 that can be configured with example MRI RF coils, coil elements, coil arrays, or circuitry according to one or more embodiments described herein. Apparatus 100 includes basic field magnet(s) 110 and a basic field magnet supply 120. Ideally, the basic field magnets 110 would produce a uniform B₀ field. However, in practice, the B₀ field may not be uniform, and may vary over an object being imaged by the MRI apparatus 100. MRI apparatus 100 can include gradient coils 135 configured to emit gradient magnetic fields like Gₓ (e.g., via an associated gradient coil 135ₓ), G_{y} (e.g., via an associated gradient coil 135_{y}) and G_{z} (e.g., via an associated gradient coil 135_{z}). The gradient coils 135 can be controlled, at least in part, by a gradient coils supply 130. In some examples, the timing, strength, and orientation of the gradient magnetic fields can be controlled, and thus selectively adapted during an MRI procedure.

MRI apparatus 100 can include a primary coil 165 configured to generate RF pulses. The primary coil 165 can be a whole body coil. The primary coil 165 can be, for example, a birdcage coil. The primary coil 165 can be controlled, at least in part, by an RF transmission unit 160. RF transmission unit 160 can provide a signal to primary coil 165.

MRI apparatus 100 can include a set of RF antennas 150 (e.g., one or more RF antennas 150₁-150_{N}, which can be as described herein). RF antennas 150 can be configured to generate RF pulses and to receive resulting magnetic resonance signals from an object to which the RF pulses are directed. In some embodiments, RF antennas 150 can be configured to inductively couple with primary coil 165 and generate RF pulses and to receive resulting magnetic resonance signals from an object to which the RF pulses are directed. In other embodiments, RF antennas 150 can be electrically coupled to a power source (e.g., RF Tx unit 160) that can drive RF antennas 150 to generate RF pulses, and RF antennas can also be configured to receive resulting magnetic resonance signals from an object to which the RF pulses are directed. In one embodiment, one or more members of the set of RF antennas 150 can be fabricated from flexible coaxial cable, or other conductive material. The set of RF antennas 150 can be connected with an RF receive unit 164.

The gradient coils supply 130 and the RF transmission units 160 can be controlled, at least in part, by a control computer 170. The magnetic resonance signals received from the set of RF antennas 150 can be employed to generate an image, and thus can be subject to a transformation process like a two dimensional fast Fourier transform (FFT) that generates pixilated image data. The transformation can be performed by an image computer 180 or other similar processing device. The image data can then be shown on a display 199. RF Rx Units 164 can be connected with control computer 170 or image computer 180. While FIG. 1 illustrates an example MRI apparatus 100 that includes various components connected in various ways, it is to be appreciated that other MRI apparatus can include other components connected in other ways, and can be employed in connection with various embodiments discussed herein.

In one embodiment, MRI apparatus 100 includes control computer 170. In one example, a member of the set of RF antennas 150 can be individually controllable by the control computer 170. A member of the set of RF antennas 150 can be an example MRI RF coil array including, for example, MRI RF coil arrays as described herein. In various embodiments, the set of RF antennas 150 can include various combinations of example embodiments of MRI RF coil arrays, elements or example embodiments of MRF RF coil arrays, including single-layer MRI RF coil elements or single-layer MRI RF coil arrays, according to various embodiments described herein.

An MRI apparatus can include, among other components, a controller (e.g., control computer 170) and an RF coil (e.g., primary coil 165) operably connected to the controller. The controller can provide the RF coil with a current, a voltage, or a control signal. The coil can be a whole body coil. The coil can inductively couple with an example MRI RF coil element, or MRI RF coil array, as described herein. Control computer 170 can provide a DC bias current, or control a DC bias control circuit to control the application of a DC bias current to MRI RF coil arrays or elements that can be part of antennas 150.

Magnetic resonance imaging (MRI) systems can employ phased array coils. A phased array coil is a coil technology used to build multiple-channel MR coils. Phased array MRI coils have the advantage of providing signal penetration similar to that provided by large coils, while having higher signal performance similar to smaller coils at a shallow depth. Phased array coils can be implemented as flexible MRI coils. A flexible MR array coil has its own advantages in work flow and patient comfort. For example, a flexible torso MR coil can be put directly on top of a patient's body and configured to conform to the body to minimize the distance between the patient and the coil. Thus, the flexible torso MR coil can receive an optimized MR signal compared to a rigid torso coil. There are multiple conventional approaches to implementing a flexible MR coil suitable for use in a phased array coil.

A first approach is to use a flexible printed circuit, such as polyamide copper laminate, and encapsulate the flexible printed circuit in a flexible material, for example, foam or fabric. The advantage of this approach is that the flexible printed circuit board still uses copper as a coil inductor. Copper has very high conductivity thus has a high signal to noise ratio (SNR). However, polyamide copper laminate is generally available only as a flat shape. This flat shape is good and reliable at bending, but less appropriate and less reliable for folding. However, polyamide copper laminate is not suitable for twisting. If a polyamide copper laminate circuit is twisted repeatedly, it requires a higher force than bending. As a result, twisting generates higher stress on the polyamide copper laminate. Therefore, the polyamide copper laminate circuit becomes less reliable.

A second approach is to use conductive ink to print an RF coil inductor on a flexible base, such as film or fabric. This approach is more flexible with respect to bending, folding and twisting. However, conventional conductive inks have significantly less conductivity than copper. Thus, approaches using conductive ink have a lower coil SNR, because of the lower conductivity compared to copper. Since SNR is one of the most important performance factors of MR coils, this second approach is less than optimal.

A third approach is to use a flexible coaxial cable to make a flexible coil. The coaxial cable braid can be used as a coil inductor in this approach. However, the conductivity of braided copper is not as good as the conductivity of solid copper, because the braided copper uses very thin wires. Therefore, this approach also suffers lower SNR compared to a similar coil that uses copper. A similar result follows if the coaxial cable is replaced with a thin flexible wire, because the thin flexible wire also comprises many very thin copper wires.

Other approaches include using a flexible capacitor to make a flexible coil. Flexible dielectric materials can be used to achieve the capacitance that an MR coil application needs. However, the flexible dielectric material's RF (Radio Frequency) loss is larger than that of commercial ceramic capacitor material, such as NGO. This creates additional SNR loss, and, again, reduces the image quality and clinical utility of the approach. In summary, most flexible RF coil approaches create additional SNR loss due to additional RF loss of the flexible conductor or dielectric material, and are thus less than optimal, particularly when used as part of a flexible phased array coil.

A coil's own RF loss (e.g., conductive or dielectric loss) impacts the coil's SNR and depends on the B₀ field strength, anatomies being imaged, and size of the coil. For example, the coil loss at a high B₀ field strength, (e.g., 3 T and above) is caused mostly from the patient being imaged. Therefore, decreasing conductor and dielectric loss does not have a significant impact on SNR performance. However, at low B₀ field strengths, such as 1 T and lower, the conductor and dielectric loss becomes dominant. Any improvement on a coil's own Q will have a larger impact on the SNR performance at lower field strength than at higher field strengths.

The human body comprises blood, muscle, fat, fluid, bones, skin and many other tissues. Muscle, for example, has a high percentage of blood and fluid in it, and blood and other fluids have reasonably good conductivities. On the other hand, bone and fat do not have a high percentage of blood and fluid, and are thus significantly less conductive than muscle. Therefore, anatomies such as wrist and knee have less loss caused by the patient anatomy than other regions. For those anatomies, the noise is dominated more by the coil conductor and dielectric loss. The opposite situation occurs for head and body anatomies, because of the greater conductivities resulting from more blood and body fluid in the region being imaged.

If the coil element size becomes smaller, the noise becomes more dependent on the coil's own conductor and dielectric loss. For example, a 10 cm diameter coil will cover an imaging volume of a*(10 cm)³, where a is scaling constant. If the 10 cm value is reduced to a smaller value, the noise from copper (i.e., the length of copper used to form the coil) decreases linearly and the noise from the patient decreases cubically. Therefore, decreasing the coil element size makes SNR more coil dominant. Various embodiments described herein provide a solution that increases an RF coil's Q factor and thus increases MR coil SNR at low B₀ field strengths, smaller coil element sizes, and low loss anatomies for use in a phased array coil.

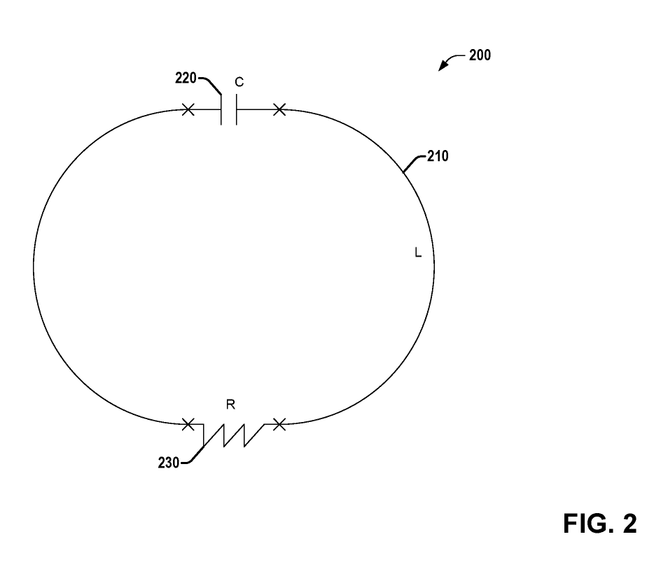

Referring to FIG. 2, illustrated is a diagram of an example one-turn coil element 200, as discussed in connection with various aspects disclosed herein. In FIG. 2, the coil conductive trace inductor 210 has inductance L (e.g., from one or more loop inductors, such as the inductance of the conductor from which the loop is formed), the equivalent capacitor 220 has capacitance C (e.g., from one or more loop capacitors, such as a distributed capacitor comprising dielectric material and conductive material from which the loop is formed), and the coil loss 230 is R, which comprises both conductor loss and dielectric loss. In this example, other losses, such as radiation loss, are ignored, as these can be ignored at low B₀ field strength and small coil element size. In an unloaded situation in which the coil is relatively far away from any anatomies, the coil Q can be written as ω₀L/R at the resonant frequency ω₀.

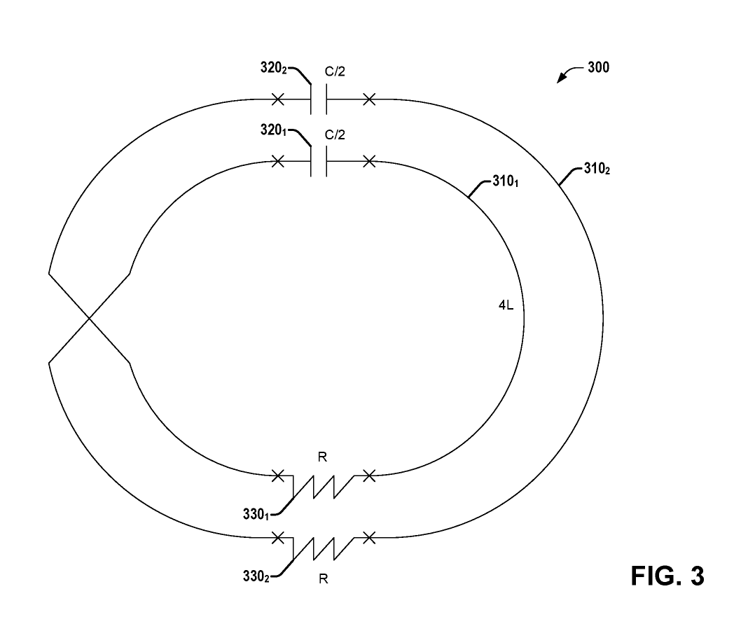

Referring to FIG. 3, illustrated is a diagram of an example two-turn coil element 300 that can be employed in or as a RF antenna in a MRI apparatus (e.g., as a RF antenna 150ᵢ in MRI apparatus 100), according to various aspects discussed herein. In various embodiments, coil element 300 can have the same diameter as coil element 200, but can comprise two turns 310₁ and 310₂, in contrast to the single-turn coil element 200. In various embodiments, the two turns can have the same diameter and be very close to one another. However, for the purposes of illustration, the two turns shown in FIG. 3 are not drawn proportionally or in relatively close proximity to one another. As can be seen by comparing FIG. 3 to FIG. 2, the coil inductance of coil element 300 is increased almost four times (to around 4 L) compared to that of coil element 200 (L), because the magnetic field generated by the same current is doubled. The coil loss (indicated for each turn at 330₁ and 330₂) is proportional to the coil circumference, so the coil loss (2R) of coil element 300 is around twice that of coil element 200 (R). As a result, the Q (computed as ω₀L/R, as noted above) of coil element 300 is almost double that of coil element 200. For a coil element with more turns than coil element 300, the coil Q is further improved. Thus, various embodiments can employ a multi-turn approach, wherein coil element(s) comprise two or more turns to provide for increased Q compared to similar single-turn coils. In embodiments employing the multi-turn approach for small element size, low field and low loss anatomies can compensate coil SNR performance if the conductive and dielectric material used is lossy. Thus, in contrast to existing flexible low field (e.g., with a B₀ of 1.5 T or less, etc.) coil elements and/or coil arrays, embodiments discussed herein can have significantly improved Q values, and thus achieve higher SNR.

Additionally, in various embodiments, coil element 300 can comprise one or more additional elements that have been omitted for clarity of illustration, but which can facilitate use of coil element 300 in or as a RF antenna for a MRI system, as a transmit (Tx) coil and/or a receive (Rx) coil. As a Tx coil, some embodiments of coil element 300 or a coil array comprising coil element 300 can inductively couple to a primary coil (e.g., WBC) and/or one or more other coil elements 300 of a coil array 400, or can be driven via a direct (e.g., electrical) connection to a power source. As a Rx coil, various embodiments of coil element 300 in a coil array with other channels can employ channel isolation circuitry or circuit elements (e.g., balun(s), etc.) to minimize interference from other channels. Additionally, because of the low amplitude of the signals received via Rx coils, coil element 300 can employ pre-amplification circuitry or circuit elements (e.g., LNA (Low Noise Amplifier), etc.).

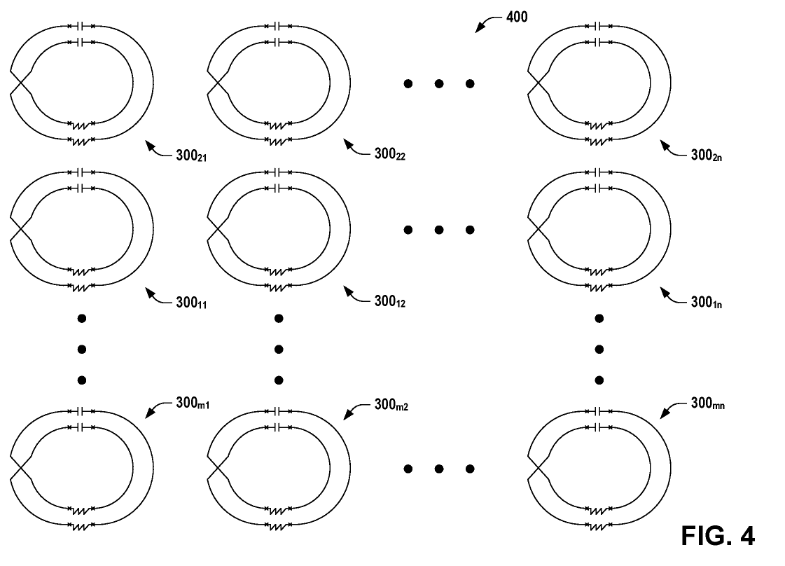

Referring to FIG. 4, illustrated is a diagram of an example coil array 400 that can be employed as a RF antenna in a MRI apparatus (e.g., as a RF antenna 150ᵢ in MRI apparatus 100), according to various aspects discussed herein. Coil array 400 can comprise a plurality of multi-turn coil elements 300ᵢⱼ, which can be arranged into m rows and n columns, where m and n are positive integers (m≥1 and n≥1, with at least one of m or n≥2, such that there are a plurality of multi-turn coil elements 300ᵢⱼ). Although for ease of illustration each multi-turn coil element 300ᵢⱼ in FIG. 4 is shown as having two turns, in various embodiments, each multi-turn coil 300ᵢⱼ can comprise two turns or more than two turns. In various embodiments, each multi-turn coil 300ᵢⱼ of array 400 can comprise the same number of turns (e.g., N turns, where N is an integer greater than 1), though in other embodiments some multi-turn coils 300ᵢⱼ can comprise different number(s) of turns than other multi-turn coils 300ᵢⱼ.

For ease of illustration, coil array 400 shows multi-turn coil elements 300ᵢⱼ separate from and non-overlapping with one another. However, in various embodiments, one or more multi-turn coil elements 300ᵢⱼ of array 400 can partially overlap each other, which can reduce mutual inductance between neighboring multi-turn coil elements 300ᵢⱼ. As examples, in a given row (or, alternatively, column), each multi-turn coil element 300ᵢⱼ of that row (or column) can partially overlap immediately neighboring multi-turn coil elements 300ᵢⱼ of that row (or column), and can either not overlap or partially overlap its nearest neighbor(s) in adjacent row(s) (or column(s)).

Additionally, although multi-turn coil elements 300ᵢⱼ of array 400 are shown arranged in one or more parallel rows that are perpendicular to one or more parallel columns, this need not be the case for various embodiments. Initially, because various embodiments discussed herein can comprise multi-turn coil elements 300ᵢⱼ made of flexible materials, the geometry can vary as a result (e.g., bending, twisting, etc., to fit anatomy for imaging, for storage, etc.). Additionally, however, even if coil array 400 is arranged in a plane as illustrated in FIG. 4, in various embodiments, rows need not be straight lines and/or parallel to one another (e.g., can deviate from being straight lines or parallel within certain threshold(s)) and/or columns need not be straight lines and/or parallel to one another (e.g., can deviate from being straight lines or parallel within certain threshold(s)).

Additionally, rows and columns need not be perpendicular. As an example, in some embodiments, a nearest multi-turn coil elements 300ᵢⱼ in row i can be offset horizontally (relative to the geometry of FIG. 4) from a nearest multi-turn coil elements 300₍ᵢ₊₁₎ⱼ in row i+1 by a given distance, such that rows and columns are non-perpendicular. As another example, each even row (or alternatively, column) of coil array 400 can be offset horizontally from each odd row (or column) of coil array 400 by a given amount, such that rows (or columns) are straight (e.g., within a threshold) lines, but columns (or rows) follow zigzag pattern(s) (e.g., within a threshold). Additional arrangements of coil array 400 are also possible.

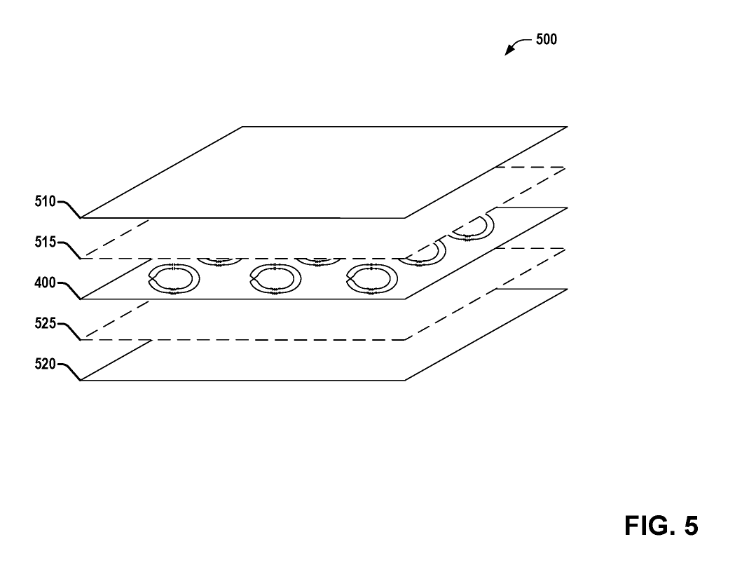

Referring to FIG. 5, illustrated is a diagram of an example apparatus 500 comprising an array 400 of multi-turn coil elements 300ᵢⱼ that can be employed as a RF antenna in a MRI apparatus (e.g., as a RF antenna 150ᵢ in MRI apparatus 100), according to various aspects discussed herein. Apparatus 500 can comprise a flexible coil array 400 according to any of the various embodiments discussed herein, wherein coil array 400 comprises materials that are flexible enough (e.g., relatively thin wire for loops of coil elements of array 400) and/or small enough (e.g., wherein rigid circuit elements are of small enough size) such that the entirety of coil array 400 is flexible, and can be easily bent, twisted, folded, etc. for storage and/or conforming to relevant anatomical regions, as well as easing operator workflow in applying a coil array. In apparatus 500, coil array 400 can be arranged between two layers 510 and 520 of flexible material (e.g., fabric, film, foam, etc.) that can cover and/or protect array 400, while providing a more comfortable patient experience during MRI imaging (e.g., which can lead to increased patient compliance and lowered chance of patient motion during imaging) and/or is suitable for use in a clinical environment. Optionally, apparatus 500 can comprise one or more additional layers of material 515 between layer 510 and array 400 and/or one or more additional layers of material 525 between array 400 and layer 520, which can provide additional padding to improve patient experience (e.g., comfort, via reduced ability to feel rigid circuit elements, etc.) and/or offer additional protection for array 400. In various embodiments, array 400 can be attached or fixed to one or more of the closest layers (e.g., one or more of 510, 515, 520, or 525, depending on the embodiment). Each of layers 510 and 520 (and 515 and/or 525, when employed) can be of any of a variety of materials, and can advantageously be of a material that can be repeatedly bent, twisted, etc. without significant degradation, and can advantageously be of a material that does not interfere with (e.g., reflect, absorb, etc.) RF signals, at least in a frequency range encompassing a working frequency of coil array 400 (e.g., the Larmor frequency of ¹H at the relevant B₀ field strength, etc.).

Various embodiments described herein can comprise a MRI transmit/receive (Tx/Rx) coil array comprising a plurality of multi-turn coil elements.

Various embodiments can comprise MRI RF coil array(s) configured to conform to one or more regions of human anatomy, for example, chest, shoulder, leg, head, neck, arm, wrist, etc. In various embodiments, a coil array as discussed herein can be flexible and employable in connection with more than one region of human anatomy.

In some embodiments, a coil array can be configured to operate in a Rx mode. In the same or other embodiments, the coil array can be configured to operate in a Tx mode. In some embodiments, a coil array can be configured as a single-layer MRI RF coil array that can alternate operate in a Tx mode and in a Rx mode.

A first example embodiment comprises a MRI RF coil array comprising: at least two coil elements in columns, and at least two coil elements in rows, where each coil element has at least two turns and the coil array works at B₀ field at 1.5 T and lower field (e.g., has a working frequency equal to a Larmor frequency of a relevant nuclei (e.g., ¹H, etc.) in a B₀ field of 1.5 T or lower, etc.). In various embodiments, each coil element of the MRI RF coil array can comprise an associated LC coil, wherein the associated LC coil comprises at least one associated inductor and at least one associated capacitor, wherein the associated LC coil is configured to resonate at a first frequency.

A second example embodiment comprises the first example embodiment, wherein the coil array is flexible.

A third example embodiment comprises the first example embodiment, wherein the coil element conductor is a small flexible coax cable.

A fourth example embodiment comprises the third example embodiment, wherein the small flexible coax cable has a diameter less than or equal to 3 mm.

A fifth example embodiment comprises the first example embodiment, wherein the coil element conductor is a thin flexible multi-stranded wire.

A sixth example embodiment comprises the fifth example embodiment, wherein the thin flexible multi-stranded wire has a diameter less than or equal to 3 mm

A seventh example embodiment comprises the first example embodiment, wherein the coil element capacitor is a distributed capacitor using a dielectric material and a conductive material.

An eighth example embodiment comprises the seventh example embodiment, wherein both the dielectric material and the conductive material are flexible.

A ninth example embodiment comprises a MRI apparatus configured with a set of one or more example multi-turn MRI RF coil arrays. The apparatus comprises one or more basic field magnets and a basic field magnet supply. Ideally, the basic field magnet(s) would produce a uniform B₀ field. However, in practice, the B₀ field may not be uniform, and may vary over an object being imaged by the MRI apparatus. Accordingly, the MRI apparatus can comprise gradient coils configured to emit gradient magnetic fields like G_{S}, G_{P} and G_{R}. The gradient coils can be controlled, at least in part, by a gradient coils supply. In various embodiments, the timing, strength, and orientation of the gradient magnetic fields can be controlled and thus selectively adapted during an MRI procedure.

The MRI apparatus of the ninth example embodiment (and of various other embodiments) can comprise a set of one or more multi-turn MRI RF antennas comprising multi-turn MRI RF coil arrays as described herein, which can optionally be directly connected to a power supply. The set of RF antennas can be configured to generate RF pulses and/or to receive resulting magnetic resonance signals from an object to which the RF pulses are directed. The RF antennas can be controlled, at least in part, by a set of RF transmission units. An RF transmission unit can provide a signal to a member of the set of RF antennas. The signal can comprise a control signal. The RF transmission unit can also provide a current or a voltage to a member of the set of RF antennas. In various embodiments, one or more members of the set of RF antennas can be configured as single-layer coils, wherein the same coil elements are configured to operate alternately in a Tx mode and in a Rx mode.

In the ninth example embodiment (and in various other embodiments), the gradient coils supply and the RF transmission units can be controlled, at least in part, by a control computer. The magnetic resonance signals received from the RF antennas can be employed to generate an image, and thus can be subject to a transformation process, such as a two dimensional FFT, that generates pixilated image data. The transformation can be performed by an image computer or other similar processing device. The image data can then be shown on a display. In one example, the MRI apparatus can include a control computer. In one example, individual member(s) of the set of RF antenna(s) can be individually controllable by the control computer.

Examples herein can include subject matter such as a method, means for performing acts or blocks of the method, at least one machine-readable medium including executable instructions that, when performed by a machine (e.g., MRI machine, for example as described herein, etc.) cause the machine to perform acts of the method or of an apparatus or system according to embodiments and examples described.

The following examples are additional embodiments.

Example 1 is a magnetic resonance imaging (MRI) radio frequency (RF) coil array configured to operate in at least one of a transmit (Tx) mode or a receive (Rx) mode, the MRI RF coil array comprising: a plurality of multi-turn coil elements, each multi-turn coil element of the plurality of multi-turn coil elements comprising: an associated LC coil of that multi-turn coil element, comprising at least one associated coil inductor, at least one associated coil capacitor, and an associated loop comprising at least two turns; wherein the plurality of multi-turn coil elements are arranged into one or more rows, wherein the plurality of multi-turn coil elements are arranged into one or more columns, and wherein the MRI RF coil array is configured to operate at a B₀ field of 1.5 T or less.

Example 2 comprises the subject matter of any variation of any of example(s) 1, wherein, for each multi-turn coil element of the plurality of multi-turn coil elements, that multi-turn coil element is a flexible coil element.

Example 3 comprises the subject matter of any variation of any of example(s) 1-2, wherein, for each multi-turn coil element of the plurality of multi-turn coil elements, an associated conductor of that multi-turn coil element is a flexible coaxial cable of that multi-turn coil element.

Example 4 comprises the subject matter of any variation of any of example(s) 3, wherein the flexible coaxial cable has a diameter of 3 mm or less.

Example 5 comprises the subject matter of any variation of any of example(s) 1-2, wherein, for each multi-turn coil element of the plurality of multi-turn coil elements, an associated conductor of that multi-turn coil element is a flexible multi-stranded wire of that multi-turn coil element.

Example 6 comprises the subject matter of any variation of any of example(s) 5, wherein the flexible multi-stranded wire has a diameter of 3 mm or less.

Example 7 comprises the subject matter of any variation of any of example(s) 1-6, wherein, for each multi-turn coil element of the plurality of multi-turn coil elements, the at least one associated coil capacitor of that multi-turn coil element is a distributed capacitor of that multi-turn coil element comprising an associated dielectric material of that multi-turn coil element and an associated conductive material of that multi-turn coil element.

Example 8 comprises the subject matter of any variation of any of example(s) 7, wherein, for each multi-turn coil element of the plurality of multi-turn coil elements, the associated dielectric material of that multi-turn coil element is flexible and the associated conductive material of that multi-turn coil element is flexible.

Example 9 comprises the subject matter of any variation of any of example(s) 1-8, wherein the associated loop of each multi-turn coil element of the plurality of multi-turn coil elements comprises N turns, wherein N is an integer greater than one.

Example 10 comprises the subject matter of any variation of any of example(s) 1-9, wherein each multi-turn coil element of the plurality of multi-turn coil elements is associated with a different channel of the MRI RF coil array.

Example 11 is an apparatus configured to be employed in connection with a magnetic resonance imaging (MRI) system, comprising: a first layer of a flexible material; a second layer of the flexible material; and a MRI radio frequency (RF) coil array configured to operate in at least one of a transmit (Tx) mode or a receive (Rx) mode, the MRI RF coil array comprising: a plurality of multi-turn coil elements, each multi-turn coil element of the plurality of multi-turn coil elements comprising: an associated LC coil of that multi-turn coil element, comprising at least one associated coil inductor, at least one associated coil capacitor, and an associated loop comprising at least two turns; wherein the plurality of multi-turn coil elements are arranged into one or more rows, wherein the plurality of multi-turn coil elements are arranged into one or more columns, and wherein the MRI RF coil array is configured to operate at a B₀ field of 1.5 T or less, wherein the MRI RF coil array is arranged between the first layer and the second layer.

Example 12 comprises the subject matter of any variation of any of example(s) 11, wherein, for each multi-turn coil element of the plurality of multi-turn coil elements, that multi-turn coil element is a flexible coil element.

Example 13 comprises the subject matter of any variation of any of example(s) 11-12, wherein, for each multi-turn coil element of the plurality of multi-turn coil elements, an associated conductor of that multi-turn coil element is a flexible coaxial cable of that multi-turn coil element.

Example 14 comprises the subject matter of any variation of any of example(s) 13, wherein the flexible coaxial cable has a diameter of 3 mm or less.

Example 15 comprises the subject matter of any variation of any of example(s) 11-12, wherein, for each multi-turn coil element of the plurality of multi-turn coil elements, an associated conductor of that multi-turn coil element is a flexible multi-stranded wire of that multi-turn coil element.

Example 16 comprises the subject matter of any variation of any of example(s) 15, wherein the flexible multi-stranded wire has a diameter of 3 mm or less.

Example 17 comprises the subject matter of any variation of any of example(s) 11-16, wherein, for each multi-turn coil element of the plurality of multi-turn coil elements, the at least one associated coil capacitor of that multi-turn coil element is a distributed capacitor of that multi-turn coil element comprising an associated dielectric material of that multi-turn coil element and an associated conductive material of that multi-turn coil element.

Example 18 comprises the subject matter of any variation of any of example(s) 17, wherein, for each multi-turn coil element of the plurality of multi-turn coil elements, the associated dielectric material of that multi-turn coil element is flexible and the associated conductive material of that multi-turn coil element is flexible.

Example 19 is a single-layer magnetic resonance imaging (MRI) radio frequency (RF) coil array configured to alternately operate in a transmit (Tx) mode and in a receive (Rx) mode, the MRI RF coil array comprising: a plurality of multi-turn coil elements, each multi-turn coil element of the plurality of multi-turn coil elements comprising: an associated LC coil of that multi-turn coil element, comprising at least one associated coil inductor, at least one associated coil capacitor, and an associated loop comprising at least two turns; wherein the plurality of multi-turn coil elements are arranged into one or more rows, wherein the plurality of multi-turn coil elements are arranged into one or more columns, wherein the MRI RF coil array is configured to operate at a B₀ field of 1.5 T or less, and wherein, in the Tx mode, the coil array is configured to generate RF signals based on one of inductive coupling to a primary coil or at least one direct connection between a power supply and at least one multi-turn coil element of the plurality of multi-turn coil elements.

Example 20 comprises the subject matter of any variation of any of example(s) 19, wherein, for each multi-turn coil element of the plurality of multi-turn coil elements, that multi-turn coil element is a flexible coil element.

Example 21 is a MRI apparatus comprising a MRI RF coil array according to any variation of any of example(s) 1-20.

Circuits, apparatus, elements, MRI RF coils, arrays, methods, and other embodiments described herein are described with reference to the drawings in which like reference numerals are used to refer to like elements throughout, and where the illustrated structures are not necessarily drawn to scale. Embodiments are to cover all modifications, equivalents, and alternatives falling within the scope of the disclosure and appended claims. In the figures, the thicknesses of lines, layers and/or regions may be exaggerated for clarity. Nothing in this detailed description (or drawings included herewith) is admitted as prior art.

Like numbers refer to like or similar elements throughout the description of the figures. When an element is referred to as being “connected” to another element, it can be directly connected to the other element or intervening elements may be present. In contrast, when an element is referred to as being “directly connected” to another element, there are no intervening elements present. Other words used to describe the relationship between elements should be interpreted in a like fashion (e.g., “between” versus “directly between,” “adjacent” versus “directly adjacent,” etc.).

In the above description some components may be displayed in multiple figures carrying the same reference signs, but may not be described multiple times in detail. A detailed description of a component may then apply to that component for all its occurrences.

The following includes definitions of selected terms employed herein. The definitions include various examples or forms of components that fall within the scope of a term and that may be used for implementation. The examples are not intended to be limiting. Both singular and plural forms of terms may be within the definitions.

References to “one embodiment”, “an embodiment”, “various embodiments,” “one example”, “an example”, or “various examples” indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrases “in one embodiment” or “in various embodiments” does not necessarily refer to the same embodiment(s), though it may.

“Circuit”, as used herein, includes but is not limited to hardware, firmware, or combinations of each to perform a function(s) or an action(s), or to cause a function or action from another circuit, logic, method, or system. Circuit can include a software controlled microprocessor, a discrete logic (e.g., ASIC), an analog circuit, a digital circuit, a programmed logic device, a memory device containing instructions, and other physical devices. A circuit can include one or more gates, combinations of gates, or other circuit components. Where multiple logical circuits are described, it may be possible to incorporate the multiple logical circuits into one physical circuit. Similarly, where a single logical circuit is described, it may be possible to distribute that single logical logic between multiple physical circuits.

“Computer-readable storage device”, as used herein, refers to a device that stores instructions or data. “Computer-readable storage device” does not refer to propagated signals. A computer-readable storage device can take forms, including, but not limited to, non-volatile media, and volatile media. Non-volatile media can include, for example, optical disks, magnetic disks, tapes, and other media. Volatile media can include, for example, semiconductor memories, dynamic memory, and other media. Common forms of a computer-readable storage device can include, but are not limited to, a floppy disk, a flexible disk, a hard disk, a magnetic tape, other magnetic medium, an application specific integrated circuit (ASIC), a compact disk (CD), other optical medium, a random access memory (RAM), a read only memory (ROM), a memory chip or card, a memory stick, and other media from which a computer, a processor or other electronic device can read.

To the extent that the term “includes” or “including” is employed in the detailed description or the claims, it is intended to be inclusive in a manner similar to the term “comprising” as that term is interpreted when employed as a transitional word in a claim.

To the extent that the term “or” is employed in the detailed description or claims (e.g., A or B) it is intended to mean “A or B or both”. The term “and/or” is used in the same manner, meaning “A or B or both”. When the applicants intend to indicate “only A or B but not both” then the term “only A or B but not both” will be employed. Thus, use of the term “or” herein is the inclusive, and not the exclusive use. See, Bryan A. Garner, A Dictionary of Modern Legal Usage 624 (2d. Ed. 1995).

To the extent that the phrase “one or more of, A, B, and C” is employed herein, (e.g., a data store configured to store one or more of, A, B, and C) it is intended to convey the set of possibilities A, B, C, AB, AC, BC, and/or ABC (e.g., the data store can store only A, only B, only C, A&B, A&C, B&C, and/or A&B&C). It is not intended to require one of A, one of B, and one of C. When the applicants intend to indicate “at least one of A, at least one of B, and at least one of C”, then the phrasing “at least one of A, at least one of B, and at least one of C” will be employed.

Although the subject matter has been described in language specific to structural features or methodological acts, it is to be understood that the subject matter defined in the appended claims is not necessarily limited to the specific features or acts described above. Rather, the specific features and acts described above are disclosed as example forms of implementing the claims.

The above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations. In addition, while a particular feature may have been disclosed with respect to only one of several implementations, such feature can be combined with one or more other features of the other implementations as may be desired and advantageous for any given or particular application.

What is claimed is:

1. A magnetic resonance imaging (MRI) radio frequency (RF) coil array configured to operate in at least one of a transmit (Tx) mode or a receive (Rx) mode, the MRI RF coil array comprising:
a plurality of multi-turn coil elements, each multi-turn coil element of the plurality of multi-turn coil elements comprising:
an associated LC coil of that multi-turn coil element, comprising at least one associated coil inductor, at least one associated coil capacitor, and an associated loop comprising at least two turns;
wherein the plurality of multi-turn coil elements are arranged into one or more rows,
wherein the plurality of multi-turn coil elements are arranged into one or more columns, and
wherein the MRI RF coil array is configured to operate at a B₀ field of 1.5 T or less.

2. The MRI RF coil array of claim 1, wherein, for each multi-turn coil element of the plurality of multi-turn coil elements, that multi-turn coil element is a flexible coil element.

3. The MRI RF coil array of claim 1, wherein, for each multi-turn coil element of the plurality of multi-turn coil elements, an associated conductor of that multi-turn coil element is a flexible coaxial cable of that multi-turn coil element.

4. The MRI RF coil array of claim 3, wherein the flexible coaxial cable has a diameter of 3 mm or less.

5. The MRI RF coil array of claim 1, wherein, for each multi-turn coil element of the plurality of multi-turn coil elements, an associated conductor of that multi-turn coil element is a flexible multi-stranded wire of that multi-turn coil element.

6. The MRI RF coil array of claim 5, wherein the flexible multi-stranded wire has a diameter of 3 mm or less.

7. The MRI RF coil array of claim 1, wherein, for each multi-turn coil element of the plurality of multi-turn coil elements, the at least one associated coil capacitor of that multi-turn coil element is a distributed capacitor of that multi-turn coil element comprising an associated dielectric material of that multi-turn coil element and an associated conductive material of that multi-turn coil element.

8. The MRI RF coil array of claim 7, wherein, for each multi-turn coil element of the plurality of multi-turn coil elements, the associated dielectric material of that multi-turn coil element is flexible and the associated conductive material of that multi-turn coil element is flexible.

9. The MRI RF coil array of claim 1, wherein the associated loop of each multi-turn coil element of the plurality of multi-turn coil elements comprises N turns, wherein N is an integer greater than one.

10. The MRI RF coil array of claim 1, wherein each multi-turn coil element of the plurality of multi-turn coil elements is associated with a different channel of the MRI RF coil array.

11. An apparatus configured to be employed in connection with a magnetic resonance imaging (MRI) system, comprising:
a first layer of a flexible material;
a second layer of the flexible material; and
a MRI radio frequency (RF) coil array configured to operate in at least one of a transmit (Tx) mode or a receive (Rx) mode, the MRI RF coil array comprising:
a plurality of multi-turn coil elements, each multi-turn coil element of the plurality of multi-turn coil elements comprising:
an associated LC coil of that multi-turn coil element, comprising at least one associated coil inductor, at least one associated coil capacitor, and an associated loop comprising at least two turns;
wherein the plurality of multi-turn coil elements are arranged into one or more rows,
wherein the plurality of multi-turn coil elements are arranged into one or more columns, and
wherein the MRI RF coil array is configured to operate at a B₀ field of 1.5 T or less,
wherein the MRI RF coil array is arranged between the first layer and the second layer.

12. The apparatus of claim 11, wherein, for each multi-turn coil element of the plurality of multi-turn coil elements, that multi-turn coil element is a flexible coil element.

13. The apparatus of claim 11, wherein, for each multi-turn coil element of the plurality of multi-turn coil elements, an associated conductor of that multi-turn coil element is a flexible coaxial cable of that multi-turn coil element.

14. The apparatus of claim 13, wherein the flexible coaxial cable has a diameter of 3 mm or less.

15. The apparatus of claim 11, wherein, for each multi-turn coil element of the plurality of multi-turn coil elements, an associated conductor of that multi-turn coil element is a flexible multi-stranded wire of that multi-turn coil element.

16. The apparatus of claim 15, wherein the flexible multi-stranded wire has a diameter of 3 mm or less.

17. The apparatus of claim 11, wherein, for each multi-turn coil element of the plurality of multi-turn coil elements, the at least one associated coil capacitor of that multi-turn coil element is a distributed capacitor of that multi-turn coil element comprising an associated dielectric material of that multi-turn coil element and an associated conductive material of that multi-turn coil element.

18. The apparatus of claim 17, wherein, for each multi-turn coil element of the plurality of multi-turn coil elements, the associated dielectric material of that multi-turn coil element is flexible and the associated conductive material of that multi-turn coil element is flexible.

19. A single-layer magnetic resonance imaging (MRI) radio frequency (RF) coil array configured to alternately operate in a transmit (Tx) mode and in a receive (Rx) mode, the MRI RF coil array comprising:
a plurality of multi-turn coil elements, each multi-turn coil element of the plurality of multi-turn coil elements comprising:
an associated LC coil of that multi-turn coil element, comprising at least one associated coil inductor, at least one associated coil capacitor, and an associated loop comprising at least two turns;
wherein the plurality of multi-turn coil elements are arranged into one or more rows,
wherein the plurality of multi-turn coil elements are arranged into one or more columns,
wherein the MRI RF coil array is configured to operate at a B₀ field of 1.5 T or less, and
wherein, in the Tx mode, the coil array is configured to generate RF signals based on one of inductive coupling to a primary coil or at least one direct connection between a power supply and at least one multi-turn coil element of the plurality of multi-turn coil elements.

20. The MRI RF coil array of claim 19, wherein, for each multi-turn coil element of the plurality of multi-turn coil elements, that multi-turn coil element is a flexible coil element.
